(19) United States
(12) Patent Application Publication
(10) Pub. No.: US 2021/0336069 A1
(43) Pub. Date: Oct. 28, 2021

(54) VARIABLE CAPACITOR

(71) Applicant: Yangtze Memory Technologies Co., Ltd., Wuhan City (CN)

(72) Inventors: Chao Sun, Wuhan City, Hubei Province (CN); Wu Tian, Wuhan City, Hubei Province (CN); Ning Jiang, Wuhan City, Hubei Province (CN); Can Zhong, Wuhan City, Hubei Province (CN); Lei Xue, Wuhan City, Hubei Province (CN)

(21) Appl. No.: 16/893,447

(22) Filed: Jun. 5, 2020

Related U.S. Application Data
(63) Continuation of application No. PCT/CN2020/086118, filed on Apr. 22, 2020.

(51) Int. Cl. H01L 29/94; H01G 7/00; H01L 27/08

(52) U.S. Cl. CPC H01L 29/94; H01L 27/0805; H01G 7/00

(57) ABSTRACT

A variable capacitor includes a semiconductor substrate, a well region, and a gate electrode. The well region is disposed in the semiconductor substrate. The gate electrode is disposed on the semiconductor substrate, and the gate electrode overlaps a part of the well region in a thickness direction of the semiconductor substrate. A conductivity type of the gate electrode is complementary to a conductivity type of the well region for improving electrical performance of the variable capacitor.

### CROSS REFERENCE TO RELATED APPLICATIONS

This application is a continuation of International Application No. PCT/CN2020/086118 filed on Apr. 22, 2020, which is incorporated herein by reference in its entirety.

### BACKGROUND OF THE INVENTION

### 1. Field of the Invention

The present disclosure relates to a variable capacitor, and more particularly, to a variable capacitor including a gate electrode.

### 2. Description of the Prior Art

There are many kinds of capacitor structures used in semiconductor integrated circuits. For example, the common capacitors used in semiconductor integrated circuits include metal-oxide-semiconductor (MOS) capacitors, metal-insulator-metal (MIM) capacitors, and variable capacitors. As the development of semiconductor integrated circuit technology progresses continuously and circuit designs in products of the new generation become smaller and more complicated than those of the former generation, the electrical performance of the capacitors is influenced, especially when the manufacturing process of the capacitors is integrated with the manufacturing process of the main components in the semiconductor integrated circuits, such as metal-oxide-semiconductor field-effect transistors (MOSFETs).

### SUMMARY OF THE INVENTION

A variable capacitor is provided in the present disclosure. A conductivity type of a gate electrode in the variable capacitor is complementary to a conductivity type of a well region in the variable capacitor for improving electrical performance of the variable capacitor.

According to an embodiment of the present disclosure, a variable capacitor is provided. The variable capacitor includes a semiconductor substrate, a well region, and a gate electrode. The well region is disposed in the semiconductor substrate. The gate electrode is disposed on the semiconductor substrate, and the gate electrode overlaps a part of the well region in a thickness direction of the semiconductor substrate. A conductivity type of the gate electrode is complementary to a conductivity type of the well region.

In some embodiments, the well region is an n-type well region, and the gate electrode is a p-type gate electrode.

In some embodiments, the gate electrode comprises p-type doped polysilicon.

In some embodiments, a work function of the gate electrode is higher than a conduction band of the semiconductor substrate.

In some embodiments, a work function of the gate electrode is higher than or equal to 5 eV.

In some embodiments, the variable capacitor further includes two source/drain regions disposed in the well region and disposed at two opposite sides of the gate electrode respectively. Each of the two source/drain regions includes an n-type doped region.

In some embodiments, the two source/drain regions are electrically connected with each other.

In some embodiments, the well region is a p-type well region, and the gate electrode is an n-type gate electrode.

In some embodiments, the gate electrode comprises n-type doped polysilicon.

In some embodiments, a work function of the gate electrode is lower than a valence band of the semiconductor substrate.

In some embodiments, a work function of the gate electrode is lower than or equal to 4.1 eV.

In some embodiments, the variable capacitor further includes two source/drain regions disposed in the well region and disposed at two opposite sides of the gate electrode respectively. Each of the two source/drain regions includes a p-type doped region.

In some embodiments, the two source/drain regions are electrically connected with each other.

In some embodiments, the semiconductor substrate comprises a silicon semiconductor substrate.

According to another embodiment of the present disclosure, a variable capacitor is provided. The variable capacitor includes a semiconductor substrate, an n-type well region, and a gate electrode. The n-type well region is disposed in the semiconductor substrate. The gate electrode is disposed on the semiconductor substrate, and the gate electrode overlaps a part of the n-type well region in a thickness direction of the semiconductor substrate. A work function of the gate electrode is higher than a conduction band of the semiconductor substrate.

In some embodiments, the gate electrode includes a metal gate electrode, and a work function of the gate electrode is higher than or equal to 5 eV.

In some embodiments, the variable capacitor further includes two source/drain regions disposed in the n-type well region and disposed at two opposite sides of the gate electrode respectively. Each of the two source/drain regions comprises an n-type doped region.

According to another embodiment of the present disclosure, a variable capacitor is provided. The variable capacitor includes a semiconductor substrate, a p-type well region, and a gate electrode. The p-type well region is disposed in the semiconductor substrate. The gate electrode is disposed on the semiconductor substrate, and the gate electrode overlaps a part of the p-type well region in a thickness direction of the semiconductor substrate. A work function of the gate electrode is lower than a valence band of the semiconductor substrate.

In some embodiments, the gate electrode includes a metal gate electrode, and a work function of the gate electrode is lower than or equal to 4.1 eV.

In some embodiments, the variable capacitor further includes two source/drain regions disposed in the p-type well region and disposed at two opposite sides of the gate electrode respectively. Each of the two source/drain regions comprises a p-type doped region.

Other aspects of the present disclosure can be understood by those skilled in the art in light of the description, the claims, and the drawings of the present disclosure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings, which are incorporated herein and form a part of the specification, illustrate embodiments of the present disclosure and, together with the description, further serve to explain the principles of the present disclosure and to enable a person skilled in the pertinent art to make and use the present disclosure.

FIG. 1 is a schematic drawing illustrating a variable capacitor according to an embodiment of the present disclosure.

FIG. 2 is a cross-sectional diagram taken along a line A-A′ in FIG. 1.

FIG. 3 is a schematic drawing illustrating an electrical connection of a variable capacitor according to an embodiment of the present disclosure.

FIG. 4 is a schematic drawing illustrating a variable capacitor according to another embodiment of the present disclosure.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer and/or section from another. Thus, a first element, component, region, layer or section discussed below could be termed a second element, component, region, layer or section without departing from the teachings of the disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “forming” or the term “disposing” are used hereinafter to describe the behavior of applying a layer of material to an object. Such terms are intended to describe any possible layer forming techniques including, but not limited to, thermal growth, sputtering, evaporation, chemical vapor deposition, epitaxial growth, electroplating, and the like.

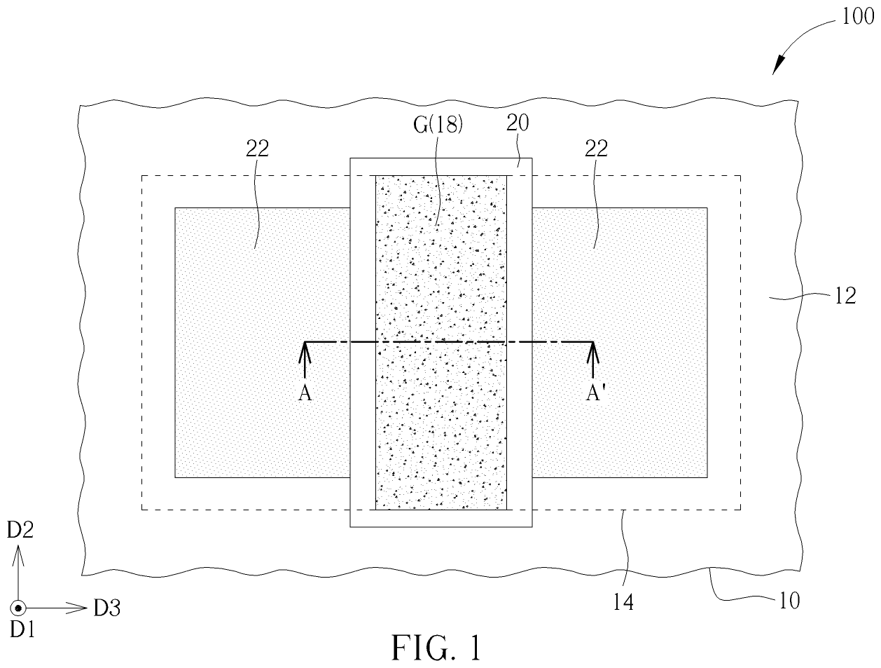

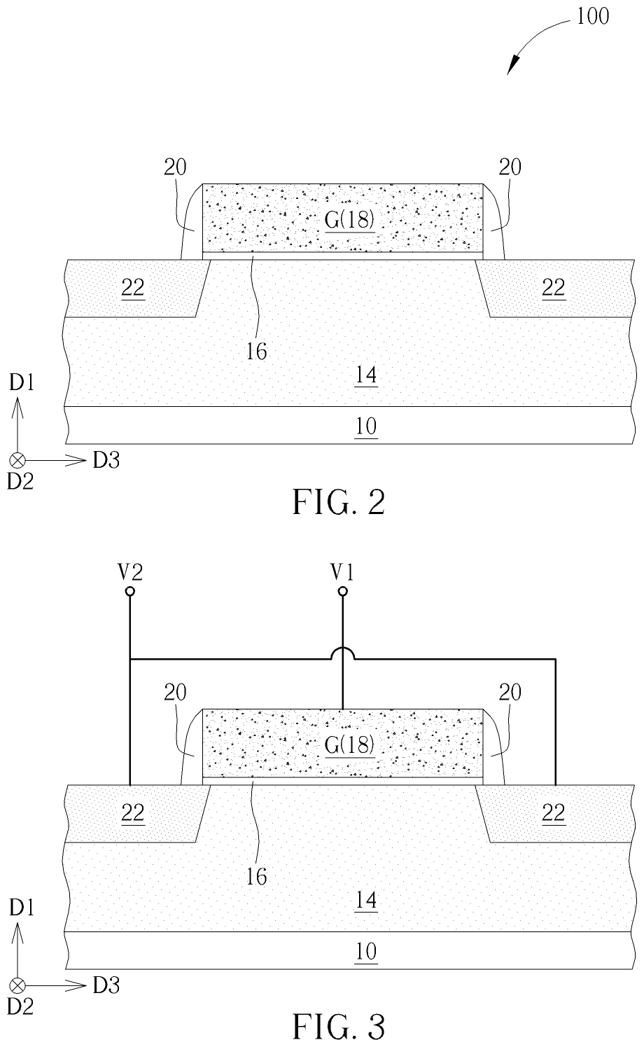

Please refer to FIG. 1 and FIG. 2. FIG. 1 is a schematic drawing illustrating a variable capacitor 100 according to an embodiment of the present disclosure, and FIG. 2 is a cross-sectional diagram taken along a line A-A′ in FIG. 1. As shown in FIG. 1 and FIG. 2, a variable capacitor 100 is provided in this embodiment. The variable capacitor 100 includes a semiconductor substrate 10, a well region 14, and a gate electrode G. The well region 14 is disposed in the semiconductor substrate 10. The gate electrode G is disposed on the semiconductor substrate 10, and the gate electrode G overlaps a part of the well region 14 in a thickness direction of the semiconductor substrate 10 (such as a first direction D1 shown in FIG. 1 and FIG. 2). A conductivity type of the gate electrode G is complementary to a conductivity type of the well region 14 for improving the electrical performance of the variable capacitor 100, such as reducing leakage current of the variable capacitor 100, but not limited thereto.

Specifically, in some embodiments, the semiconductor substrate 10 may include a silicon semiconductor substrate, a silicon germanium semiconductor substrate, a silicon-on-insulator (SOI) substrate, or a semiconductor substrate made of other suitable materials and/or having other suitable structures. The well region 14 may be an n-type well region or a p-type well region formed by implanting suitable dopants into the semiconductor substrate 10. For example, a dopant used to form the n-type well region may include phosphorus (P), arsenic (As), or other suitable n-type dopants, and a dopant used to form the p-type well region may include boron (B), gallium (Ga), or other suitable p-type dopants.

In this embodiment, the conductivity type of the gate electrode G is complementary to the conductivity type of the well region 14. In other words, the gate electrode G is a p-type gate electrode when the well region 14 is an n-type well region, and the gate electrode G is an n-type gate electrode when the well region 14 is a p-type well region. In some embodiments, the gate electrode G may include a first gate material layer 18, and the first gate material layer 18 may include a doped semiconductor material or other suitable electrically conductive materials. The doped semiconductor material described above may be formed by implanting suitable dopants into a semiconductor material. For example, a dopant used to form the n-type gate electrode may include phosphorus, arsenic, or other suitable n-type dopants, and a dopant used to form the p-type gate electrode may include boron, gallium, or other suitable p-type dopants. In other words, the dopant in the gate electrode G may be different from the dopant in the well region 14.

In some embodiments, the first gate material layer 18 may include a doped polysilicon layer or other suitable doped semiconductor layers. For example, the gate electrode G may include p-type doped polysilicon when the well region 14 is an n-type well region, and the gate electrode G may include n-type doped polysilicon when the well region 14 is a p-type well region, but not limited thereto.

In some embodiments, the variable capacitor 100 may further include a gate dielectric layer 16 and two source/drain regions 22. The gate dielectric layer 16 may be disposed between the gate electrode G and the semiconductor substrate 10 in the first direction D1. The gate dielectric layer 16 may include silicon oxide, silicon oxynitride, a high dielectric constant (high-k) material, or other appropriate dielectric materials. The high-k material mentioned above may include hafnium oxide (HfO₂), hafnium silicon oxide (HfSiO₄), hafnium silicon oxynitride (HfSiON), aluminum oxide (Al₂O₃), tantalum oxide (Ta₂O₅), zirconium oxide (ZrO₂), or other appropriate high-k materials.

The two source/drain regions 22 may be disposed in the well region 14 and disposed at two opposite sides of the gate electrode G respectively. In some embodiments, the gate electrode G may be elongated in a second direction D2, the two source/drain regions 22 may be disposed at two opposite sides of the gate electrode G in a third direction D3 respectively, and the third direction D3 may be substantially orthogonal to the second direction D2, but not limited thereto. Each of the two source/drain regions 22 may include a doped region formed by implanting suitable dopants into the semiconductor substrate 10 and the well region 14. Each of the two source/drain regions 22 may include an n-type doped region when the well region 14 is an n-type well region, and each of the two source/drain regions 22 may include a p-type doped region when the well region 14 is a p-type well region, but not limited thereto.

In some embodiments, a dopant used to form the n-type doped region may include phosphorus, arsenic, or other suitable n-type dopants, and a dopant used to form the p-type doped region may include boron, gallium, or other suitable p-type dopants. The dopant in the two source/drain regions 22 may be identical to or different from the dopant in the well region 14. In some embodiments, the conductivity type of the two source/drain regions 22 may be identical to the conductivity type of the well region 14, and the dopant concentration in the source/drain region 22 may be higher than the dopant concentration in the well region 14, but not limited thereto. Therefore, the source/drain region 22 may be regarded as an n+ doped region when the well region 14 is an n-type well region, and the source/drain region 22 may be regarded as a p+ doped region when well region 14 is a p-type well region, but not limited thereto.

In some embodiments, an isolation structure 12 may be disposed in the semiconductor substrate 10 and surround a part of the well region 14, and the well region 14 surrounded by the isolation structure 12 may be regarded as an active region of the variable capacitor 100, but not limited thereto. The isolation structure 12 may include a single layer or multiple layers of insulation material, such as silicon oxide, silicon nitride, silicon oxynitride, or other suitable insulation materials. In some embodiments, the isolation structure 12 may be regarded as a shallow trench isolation (STI) structure formed in the semiconductor substrate 10, but not limited thereto.

In some embodiments, the variable capacitor 100 may further include a spacer structure 20 formed on a sidewall of the gate electrode G and a sidewall of the gate dielectric layer 16. The spacer structure 20 may include a single layer or multiple layers of insulation materials, such as silicon oxide, silicon nitride, silicon oxynitride, or other suitable insulation materials. In some embodiments, the spacer structure 20 may overlap a part of the source/drain regions 22 in the first direction D1, and the gate electrode G may overlap a part of the source/drain regions 22 in the first direction D1, but not limited thereto.

Please refer to FIG. 3. FIG. 3 is a schematic drawing illustrating an electrical connection of a variable capacitor according to an embodiment of the present disclosure. As shown in FIG. 3, in some embodiments, the gate electrode G may be electrically connected to a first voltage terminal V1, and the two source/drain regions 22 may be electrically connected to a second voltage terminal V2 different from the first voltage terminal V1. In some embodiments, the two source/drain regions 22 may be electrically connected with each other, but not limited thereto. In the variable capacitor of this embodiment, the capacitance of the variable capacitor may vary and be controlled by adjusting the voltage applied to the gate electrode G and/or the voltage applied to the two source/drain regions 22. Therefore, the variable capacitor in the present disclosure may be regarded as a MOS varactor, but not limited thereto.

In the present disclosure, the conductivity type of the gate electrode G is complementary to the conductivity type of the well region 14 for improving the electrical performance of the variable capacitor 100, such as reducing leakage current of the variable capacitor, but not limited thereto. For instance, in a normal n-type variable capacitor, the well region is an n-type well region, the source/drain regions are n-type doped regions, and the gate electrode is an n-type gate electrode. When the voltage applied to the n-type gate electrode in the normal n-type variable capacitor is about 2 volts, the potential difference between two opposite sides of the gate dielectric layer may be about 1.9 volts. However, in the variable capacitor of the present disclosure, the potential difference between two opposite sides of the gate dielectric layer 16 may be reduced to about 1.02 volts because the gate electrode G is a p-type gate electrode having a work function higher than a work function of the n-type gate electrode used in the normal n-type variable capacitor. The smaller potential difference between two opposite sides of the gate dielectric layer 16 may result in the reduction of leakage current in the variable capacitor of the present disclosure. For example, the leakage current may be reduced from 5.8E-7 amperes (A) to 1.79E-9 A when the gate voltage is about 1.2 volts and the n-type gate electrode is replaced by the p-type gate electrode in the n-type variable capacitor, and the capacitance of the n-type variable capacitor may be slightly reduced from 1.20E-13 farads (F) to 1.02E-13 F, but not limited thereto.

In some embodiments, the work function of the gate electrode G may be higher than a conduction band of the semiconductor substrate 10 when the well region 14 is an n-type well region. For example, the conduction band of the semiconductor substrate 10 may be about 4.1 eV when the semiconductor substrate 10 is a silicon semiconductor substrate, but not limited thereto. The work function of the gate electrode G may be higher than 4.1 eV, higher than 4.5 eV, higher than or equal to 5 eV, or range within other suitable ranges (such as a range from 4.8 eV to 5 eV) when the well region 14 is an n-type well region and the variable capacitor may be regarded as an n-type variable capacitor, but not limited thereto. The p-type dopant described above may be used to increase the work function of the gate electrode G, but not limited thereto.

In some embodiments, the work function of the gate electrode G may be lower than a valence band of the semiconductor substrate 10 when the well region 14 is a p-type well region. For example, the valence band of the semiconductor substrate 10 may be about 5 eV when the semiconductor substrate 10 is a silicon semiconductor substrate, but not limited thereto. The work function of the gate electrode G may be lower than 5 eV, lower than 4.5 eV, lower than or equal to 4.1 eV, or range within other suitable ranges (such as a range from 4.1 eV to 4.3 eV) when the well region 14 is a p-type well region and the variable capacitor may be regarded as a p-type variable capacitor, but not limited thereto. The n-type dopant described above may be used to decrease the work function of the gate electrode G, but not limited thereto.

It is worth noting that the work function of the gate electrode G may be adjusted by controlling the concentration of the dopant in the gate electrode G, the condition of the manufacturing process of forming the gate electrode G, the condition of the post treatment (such as a thermal treatment) applied to the gate electrode G, and/or other factors in the processes of forming the variable capacitor. A gate electrode merely including the same component of the gate electrode G (such as the dopants described above) does not necessarily have the work function of the gate electrode G described above. There are many techniques developed based on different physical effects to measure the electronic work function of a sample. For example, method employing electron emission from the sample induced by photon absorption, by high temperature, due to an electric field, or using electron tunneling may be used to measure the work function of the sample. Additionally, methods making use of the contact potential difference between the sample and a reference electrode may also be used to measure the work function of the sample.

In the present disclosure, the conductivity type of the gate electrode G is complementary to the conductivity type of the well region 14 for improving the electrical performance of the variable capacitor. Therefore, in the present disclosure, the thickness of the gate dielectric layer 16 does not have to be increased for reducing the leakage current of the variable capacitor, the area occupied by the variable capacitor does not have to be increased for maintaining specific capacitance while the thickness of the gate dielectric layer 16 is increased, and the manufacturing process of the variable capacitor with reduced leakage current may be integrated with the manufacturing process of the semiconductor device having a relatively thinner gate dielectric layer.

The following description will detail the different embodiments of the present disclosure. To simplify the description, identical components in each of the following embodiments are marked with identical symbols. For making it easier to understand the differences between the embodiments, the following description will detail the dissimilarities among different embodiments and the identical features will not be redundantly described.

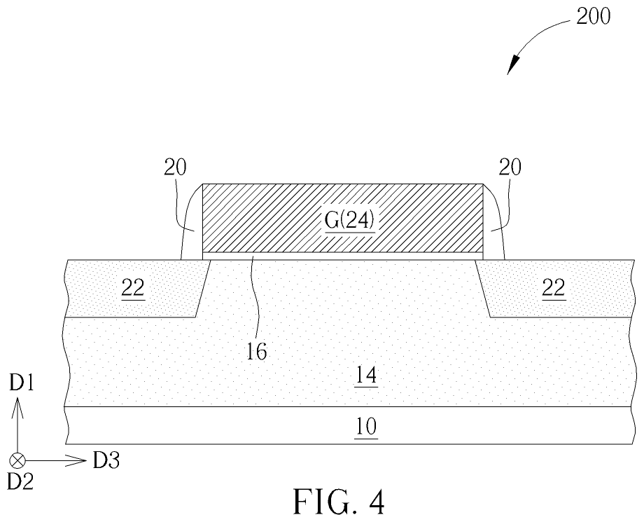

Please refer to FIG. 4. FIG. 4 is a schematic drawing illustrating a variable capacitor 200 according to another embodiment of the present disclosure. As shown in FIG. 4, the variable capacitor 200 includes the semiconductor substrate 10, the well region 14, the gate dielectric layer 16, the two source/drain regions 22, and the gate electrode G. In some embodiments, the gate electrode G may include a second gate material layer 24, and the second gate material layer 24 may include a metallic conductive material or other suitable electrically conductive materials. Therefore, the gate electrode G may include a metal gate electrode, but not limited thereto. In addition, the well region 14 may include an n-type well region or a p-type well region, and the conductivity type of the two source/drain regions 22 may be identical to the conductivity type of the well region 14.

In some embodiments, the well region 14 may be an n-type well region disposed in the semiconductor substrate 10. The two source/drain regions 22 may be disposed in the n-type well region and disposed at two opposite sides of the gate electrode G respectively, and each of the two source/drain regions 22 may include an n-type doped region, but not limited thereto. The gate electrode G is disposed on the semiconductor substrate 10, and the gate electrode G may overlap a part of the n-type well region in the thickness direction of the semiconductor substrate 10 (such as the first direction D1 shown in FIG. 4). A work function of the gate electrode G is higher than a conduction band of the semiconductor substrate 10 for improving the electrical performance of the variable capacitor 200, such as reducing leakage current of the variable capacitor 200, but not limited thereto. For example, the conduction band of the semiconductor substrate 10 may be about 4.1 eV when the semiconductor substrate 10 is a silicon semiconductor substrate, but not limited thereto. The work function of the gate electrode G may be higher than 4.1 eV, higher than 4.5 eV, higher than or equal to 5 eV, or range within other suitable ranges (such as a range from 4.8 eV to 5 eV) when the well region 14 is an n-type well region and the variable capacitor 200 may be regarded as an n-type variable capacitor, but not limited thereto. In some embodiments, the second gate material layer 24 may include nickel (Ni), cobalt (Co), gold (Au), platinum (Pt), titanium (Ti), tungsten (W), a silicide of materials described above, a composite of the materials described above, an alloy of the materials described above, or other suitable conductive materials having a work function within the ranges described above.

In some embodiments, the well region 14 may be a p-type well region disposed in the semiconductor substrate 10. The two source/drain regions 22 may be disposed in the p-type well region and disposed at two opposite sides of the gate electrode G respectively, and each of the two source/drain regions 22 may include a p-type doped region, but not limited thereto. The gate electrode G is disposed on the semiconductor substrate, and the gate electrode G may overlap a part of the p-type well region in the first direction D1. The work function of the gate electrode G is lower than a valence band of the semiconductor substrate 10 for improving the electrical performance of the variable capacitor 200, such as reducing leakage current of the variable capacitor 200, but not limited thereto. For example, the valence band of the semiconductor substrate 10 may be about 5 eV when the semiconductor substrate 10 is a silicon semiconductor substrate, but not limited thereto. The work function of the gate electrode G may be lower than 5 eV, lower than 4.5 eV, lower than or equal to 4.1 eV, or range within other suitable ranges (such as a range from 4.1 eV to 4.3 eV) when the well region 14 is a p-type well region and the variable capacitor 200 may be regarded as a p-type variable capacitor, but not limited thereto. In some embodiments, the second gate material layer 24 may include tantalum (Ta), aluminum (Al), indium (In), magnesium (Mg), manganese (Mn), titanium (Ti), tungsten (W), a silicide of materials described above, a composite of the materials described above, an alloy of the materials described above, or other suitable conductive materials having a work function within the ranges described above.

It is worth noting that the work function of the gate electrode G may be adjusted by controlling the material composition of the gate electrode G, the condition of the manufacturing process of forming the gate electrode G, the condition of the post treatment (such as a thermal treatment) applied to the gate electrode G, and/or other factors in the processes of forming the variable capacitor. A gate electrode merely including the same component of the gate electrode G (such as the metallic materials described above) does not necessarily have the work function of the gate electrode G described above.

To summarize the above descriptions, in the variable capacitor according to the present disclosure, the conductivity type of the gate electrode in the variable capacitor is complementary to the conductivity type of the well region in the variable capacitor. For example, the n-type gate electrode in the n-type variable capacitor is replaced by the p-type gate electrode, and the p-type gate electrode in the p-type variable capacitor is replaced by the n-type gate electrode. The electrical performance of the variable capacitor, such as the leakage current of the variable capacitor, may be improved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A variable capacitor, comprising:
a semiconductor substrate;
a well region disposed in the semiconductor substrate; and
a gate electrode disposed on the semiconductor substrate, wherein the gate electrode overlaps a part of the well region in a thickness direction of the semiconductor substrate, and a conductivity type of the gate electrode is complementary to a conductivity type of the well region.

2. The variable capacitor according to claim 1, wherein the well region is an n-type well region, and the gate electrode is a p-type gate electrode.

3. The variable capacitor according to claim 2, wherein the gate electrode comprises p-type doped polysilicon.

4. The variable capacitor according to claim 2, wherein a work function of the gate electrode is higher than a conduction band of the semiconductor substrate.

5. The variable capacitor according to claim 2, wherein a work function of the gate electrode is higher than or equal to 5 eV.

6. The variable capacitor according to claim 2, further comprising:
two source/drain regions disposed in the well region and disposed at two opposite sides of the gate electrode respectively, wherein each of the two source/drain regions comprises an n-type doped region.

7. The variable capacitor according to claim 6, wherein the two source/drain regions are electrically connected with each other.

8. The variable capacitor according to claim 1, wherein the well region is a p-type well region, and the gate electrode is an n-type gate electrode.

9. The variable capacitor according to claim 8, wherein the gate electrode comprises n-type doped polysilicon.

10. The variable capacitor according to claim 8, wherein a work function of the gate electrode is lower than a valence band of the semiconductor substrate.

11. The variable capacitor according to claim 8, wherein a work function of the gate electrode is lower than or equal to 4.1 eV.

12. The variable capacitor according to claim 8, further comprising:
two source/drain regions disposed in the well region and disposed at two opposite sides of the gate electrode respectively, wherein each of the two source/drain regions comprises a p-type doped region.

13. The variable capacitor according to claim 12, wherein the two source/drain regions are electrically connected with each other.

14. The variable capacitor according to claim 1, wherein the semiconductor substrate comprises a silicon semiconductor substrate.

15. A variable capacitor, comprising:
a semiconductor substrate;
an n-type well region disposed in the semiconductor substrate; and
a gate electrode disposed on the semiconductor substrate, wherein the gate electrode overlaps a part of the n-type well region in a thickness direction of the semiconductor substrate, and a work function of the gate electrode is higher than a conduction band of the semiconductor substrate.

16. The variable capacitor according to claim 15, wherein the gate electrode comprises a metal gate electrode, and a work function of the gate electrode is higher than or equal to 5 eV.

17. The variable capacitor according to claim 15, further comprising:
two source/drain regions disposed in the n-type well region and disposed at two opposite sides of the gate electrode respectively, wherein each of the two source/drain regions comprises an n-type doped region.

18. A variable capacitor, comprising:
a semiconductor substrate;
a p-type well region disposed in the semiconductor substrate; and
a gate electrode disposed on the semiconductor substrate, wherein the gate electrode overlaps a part of the p-type well region in a thickness direction of the semiconductor substrate, and a work function of the gate electrode is lower than a valence band of the semiconductor substrate.

19. The variable capacitor according to claim 18, wherein the gate electrode comprises a metal gate electrode, and a work function of the gate electrode is lower than or equal to 4.1 eV.

20. The variable capacitor according to claim 18, further comprising:
two source/drain regions disposed in the p-type well region and disposed at two opposite sides of the gate electrode respectively, wherein each of the two source/drain regions comprises a p-type doped region.
